(19) United States
(12) Patent Application Publication
(10) Pub. No.: US 2025/0267840 A1
(43) Pub. Date: Aug. 21, 2025

(54) THREE-DIMENSIONAL SEMICONDUCTOR DEVICE AND METHOD FOR MANUFACTURING THE SAME

(71) Applicant: Samsung Electronics Co., Ltd., Suwon-si (KR)

(72) Inventors: GYUHWAN OH, Suwon-si (KR); SEOKHAN PARK, Suwon-si (KR); Bowon YOO, Suwon-si (KR); Jinwoo HAN, Suwon-si (KR)

(21) Appl. No.: 18/962,136

(22) Filed: Nov. 27, 2024

(30) Foreign Application Priority Data
Feb. 16, 2024 (KR) 10-2024-0022731

(51) Int. Cl. H10B 12/00

(52) U.S. Cl. CPC H10B 12/30; H10B 12/05

(57) ABSTRACT

A three-dimensional semiconductor device includes a semiconductor pattern spaced apart from a substrate, and extending along a first direction parallel to a lower surface of the substrate, a word line surrounding the semiconductor pattern, and extending along a second direction parallel to the lower surface of the substrate, and crossing the first direction, and a bit line extending along a first side surface of the semiconductor pattern along a third direction perpendicular to the lower surface of the substrate, wherein the word line includes a first gate electrode, a second gate electrode on a first side surface of the first gate electrode, and a third gate electrode on a second surface opposite to the first side surface of the first gate electrode, and a work function of each of the second and third gate electrodes is smaller than a work function of the first gate electrode.

### CROSS-REFERENCE TO RELATED APPLICATIONS

This U.S. non-provisional patent application claims priority under 35 U.S.C. § 119 of Korean Patent Application No. 10-2024-0022731, filed on Feb. 16, 2024, in the Korean Intellectual Property Office, the entire contents of which are hereby incorporated by reference.

### BACKGROUND

The present disclosure herein relates to a three-dimensional semiconductor device and a method for manufacturing the same, and more particularly, to a three-dimensional semiconductor device with more improved reliability and integration.

Semiconductor devices are attracting attention as an important component in the electronics industry due to characteristics such as miniaturization, multi-functionality, and/or low manufacturing cost. A semiconductor device may be a semiconductor memory device that stores logical data, a semiconductor logic device that computes and processes the logical data, and a hybrid semiconductor device that includes memory components and logical components.

Recently, due to high speed and low power consumption of an electronic apparatus, high operation speed, low operation voltage, and/or the like are/is also typically required for the semiconductor device built thereinto, and in order to satisfy such requirements, a more integrated semiconductor device is needed. However, as semiconductor devices become more highly integrated, electrical characteristics and production yield of the semiconductor devices may decrease. Accordingly, a lot of research on improving the electrical characteristics and the production yield of semiconductor devices is being conducted.

### SUMMARY

Aspects of the present disclosure provides a three-dimensional semiconductor device with improved reliability. However, other benefits may also be realized from the various embodiments disclosed herein.

An embodiment of the inventive concept provides a three-dimensional semiconductor device including a semiconductor pattern spaced apart from a substrate, and extending along a first direction parallel to a lower surface of the substrate, a word line surrounding the semiconductor pattern, and extending along a second direction parallel to the lower surface of the substrate, and crossing the first direction, and a bit line extending along a first side surface of the semiconductor pattern along a third direction perpendicular to the lower surface of the substrate, wherein the word line includes a first gate electrode, a second gate electrode on a first side surface of the first gate electrode, and a third gate electrode on a second surface opposite to the first side surface of the first gate electrode, and a work function of each of the second and third gate electrodes is smaller than a work function of the first gate electrode.

In an embodiment of the inventive concept, a three-dimensional semiconductor device includes a semiconductor pattern spaced apart from a substrate, and extending along a first direction parallel to a lower surface of the substrate, a word line surrounding the semiconductor pattern, and extending along a second direction parallel to the lower surface of the substrate, and crossing the first direction, and a bit line extending along a first side surface of the semiconductor pattern along a third direction perpendicular to the lower surface of the substrate, wherein the word line includes a first gate electrode including a first material, a second gate electrode provided on a first side surface of the first gate electrode, and including a second material, and a third gate electrode provided on a second side surface opposite to the first side surface of the first gate electrode, and including a third material, the first material includes a material different from the second and third materials, and a work function of each of the second material and the third material is smaller than a work function of the first material.

In an embodiment of the inventive concept, a three-dimensional semiconductor device includes a first stack structure on a substrate, and a second stack structure adjacent to the first stack structure in a first direction parallel to a lower surface of the substrate, and a data storage pattern between the first stack structure and the second stack structure, wherein the first stack structure includes a first semiconductor pattern spaced apart from the substrate, and extending along the first direction, a first word line surrounding the first semiconductor pattern, and extending along a second direction parallel to the lower surface of the substrate, and crossing the first direction, and a first bit line extending along a first side surface of the first semiconductor pattern along a third direction perpendicular to the lower surface of the substrate, the first word line includes a first gate electrode, a second gate electrode on a first side surface of the first gate electrode, and a third gate electrode on a second side surface opposite to the first side surface of the first gate electrode, and a work function of each of the second and third gate electrodes is smaller than a work function of the first gate electrode.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a circuit diagram schematically illustrating a three-dimensional semiconductor device according to an embodiment of the inventive concept;

FIGS. 2A, 2B, and 2C are schematic perspective views of a three-dimensional semiconductor device according to an embodiment of the inventive concept;

FIG. 3 is a plan view of a three-dimensional semiconductor device according to an embodiment of the inventive concept;

FIG. 4 is a perspective view illustrating semiconductor patterns, word lines, bit lines, and a data storage pattern of a three-dimensional semiconductor device according to an embodiment of the inventive concept;

FIG. 5A is a cross-sectional view corresponding to line A-A′ in FIG. 3;

FIG. 5B is a cross-sectional view corresponding to line B-B′ in FIG. 3;

FIGS. 6A to 6C are enlarged views corresponding to PI in FIG. 5A; and

FIGS. 7 to 20 are diagrams illustrating a method for manufacturing a three-dimensional semiconductor device according to an embodiment of the inventive concept.

### DETAILED DESCRIPTION

Hereinafter, in order to specifically describe the inventive concept, embodiments according to the inventive concept will be described in more detail with reference to the accompanying drawings.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

An item, layer, or portion of an item or layer described as extending “lengthwise” in a particular direction has a length in the particular direction and a width perpendicular to that direction, where the length is greater than the width, unless the context indicates otherwise.

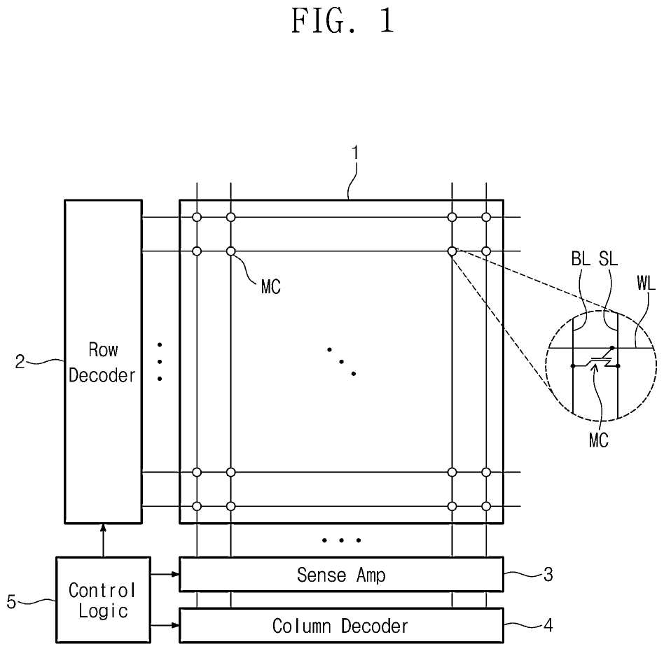

FIG. 1 is a circuit diagram schematically illustrating a three-dimensional semiconductor device according to an embodiment of the inventive concept.

Referring to FIG. 1, the three-dimensional semiconductor device may include a memory cell array 1, a row decoder 2, a sense amplifier 3, a column decoder 4, and a control logic 5. A semiconductor device, as described herein, may be a semiconductor chip, for example, formed on a die and separated from a wafer. A semiconductor device as described herein may also be a stack of semiconductor chips, or a semiconductor package including one or more semiconductor chips.

The memory cell array 1 may include word lines WL, bit lines BL, source lines SL, and memory cells MC. The memory cells MC may be three-dimensionally arranged, and a memory cell MC may be connected to one word line WL, one bit line BL, and one source line SL. In an embodiment, the memory cells MC may be each composed of one transistor including a memory film or layer (or a data storage film or layer).

The row decoder 2 may decode an externally input address input to select any one among the word lines WL of the memory cell array 1. The address decoded by the row decoder 2 may be supplied to a row driver (not shown), and the row driver may supply a predetermined voltage to each of a selected word line WL and non-selected word lines WL in response to control by control logic 5.

The sense amplifier 3 may sense and amplify a voltage difference between a selected bit line BL according to an address decoded by the column decoder 4 and a reference bit line BL to output the same.

The column decoder 4 may provide a data transmission path between the sense amplifier 3 and an external unit (for example, a memory controller). The column decoder 4 may decode an externally input address input to select any one among the bit lines BL.

The control logic 5 may generate control signals that control an operation of writing or reading data to/from the memory cell array 1.

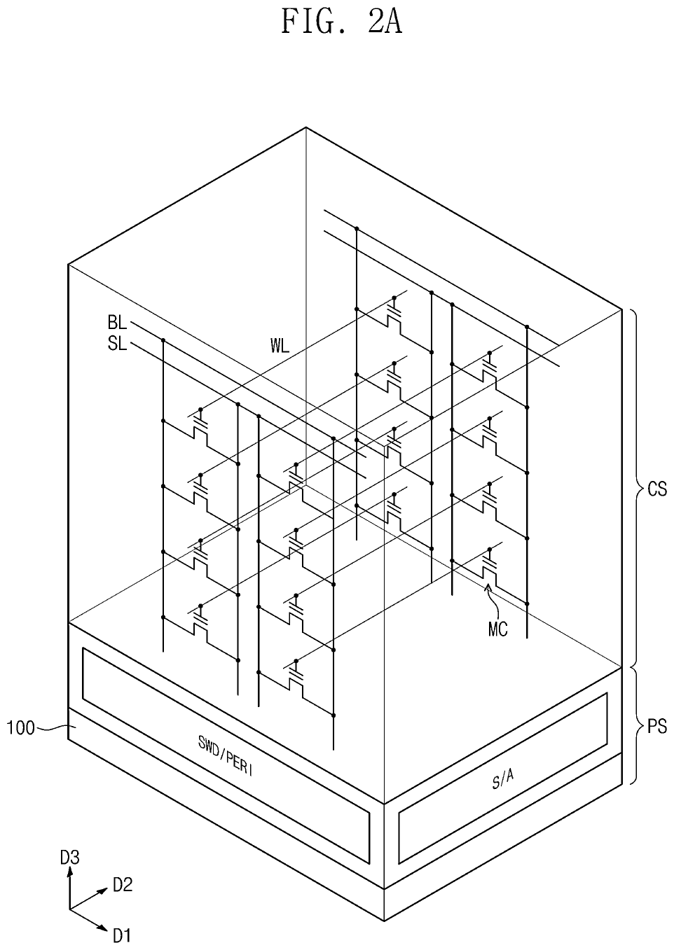

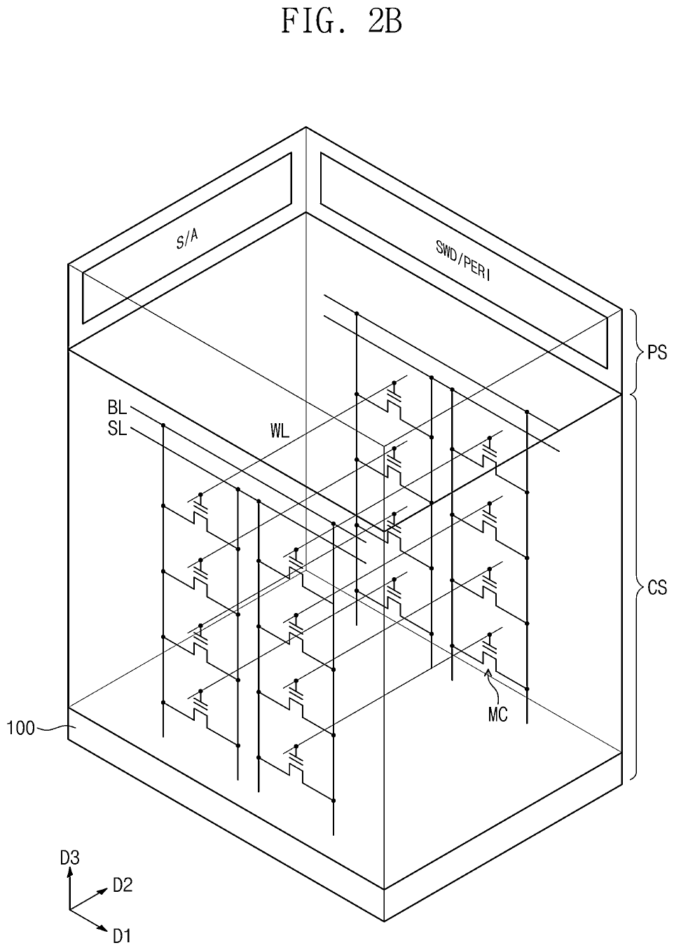

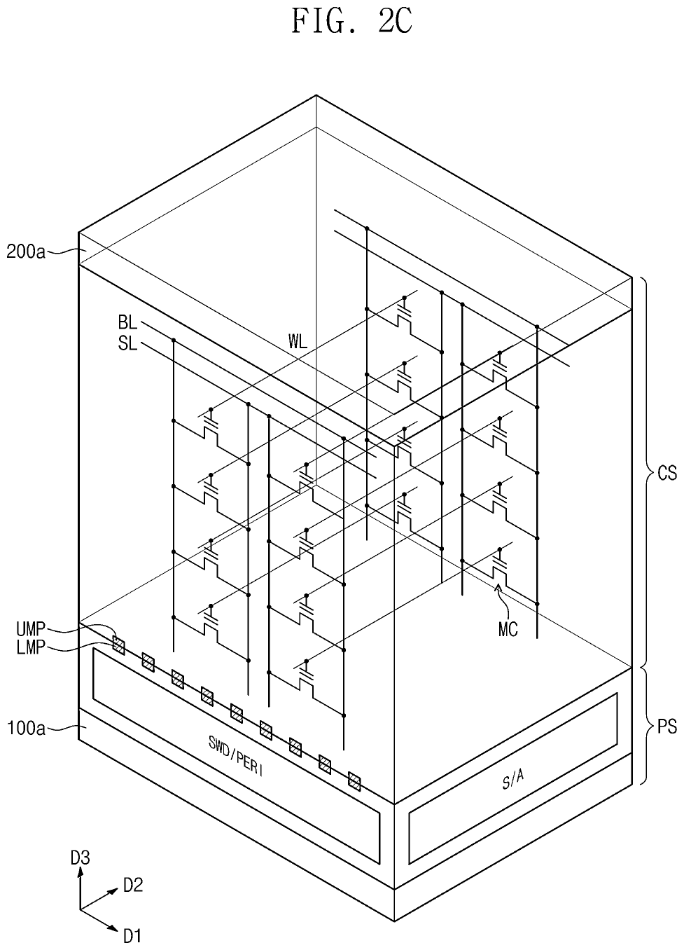

FIGS. 2A, 2B, and 2C are schematic perspective views of a three-dimensional semiconductor device according to an embodiment of the inventive concept.

Referring to FIG. 2A, the three-dimensional semiconductor device may include a substrate 100, a peripheral circuit structure PS on the substrate 100, and a cell array structure CS on the peripheral circuit structure PS.

The peripheral circuit structure PS may include core and peripheral circuits formed on the substrate 100. The core and peripheral circuits may include the row and column decoders 2 and 4 (see FIG. 1), the sense amplifier 3 (see FIG. 1), and the control logic 5 (see FIG. 1) described with reference to FIG. 1.

The substrate 100 may have a form of a plate extending along a plane defined by a first direction D1 and a second direction D2. The first direction D1 and the second direction D2 may be parallel to a lower surface of the substrate 100, and may cross each other. For example, the first direction D1 and the second direction D2 may be horizontal directions perpendicular to each other. The peripheral circuit structure PS and the cell array structure CS may be sequentially stacked on the substrate 100 in a third direction D3 orthogonal to the lower surface of the substrate 100.

The cell array structure CS may include the bit lines BL, the source lines SL, the word lines WL, and the memory cells MC therebetween. The memory cells MC may be each connected to one word line WL, one bit line BL, and one source line SL.

Referring to FIG. 2B, a semiconductor device may include the cell array structure CS on the substrate 100, and the peripheral circuit structure PS on the cell array structure CS. The cell array structure CS may be disposed between the substrate 100 and the peripheral circuit structure PS. The peripheral circuit structure PS may include the core and peripheral circuits.

Referring to FIG. 2C, the semiconductor device may have a chip to chip (C2C) structure. The peripheral circuit structure PS may include a first substrate 100a. Lower metal pads LMP may be provided to an uppermost portion of the peripheral circuit structure PS. The lower metal pads LMP may be electrically connected to the core and peripheral circuits. The lower metal pads LMP may be bonded to upper metal pads UMP of the cell array structure CS.

The cell array structure CS may include a second substrate 200a, and the upper metal pads UMP may be provided to a lowermost portion of the cell array structure CS. The upper metal pads UMP may be electrically connected to the bit lines BL, the source lines SL, and the word lines WL. The upper metal pads UMP may be electrically connected to the memory cells MC.

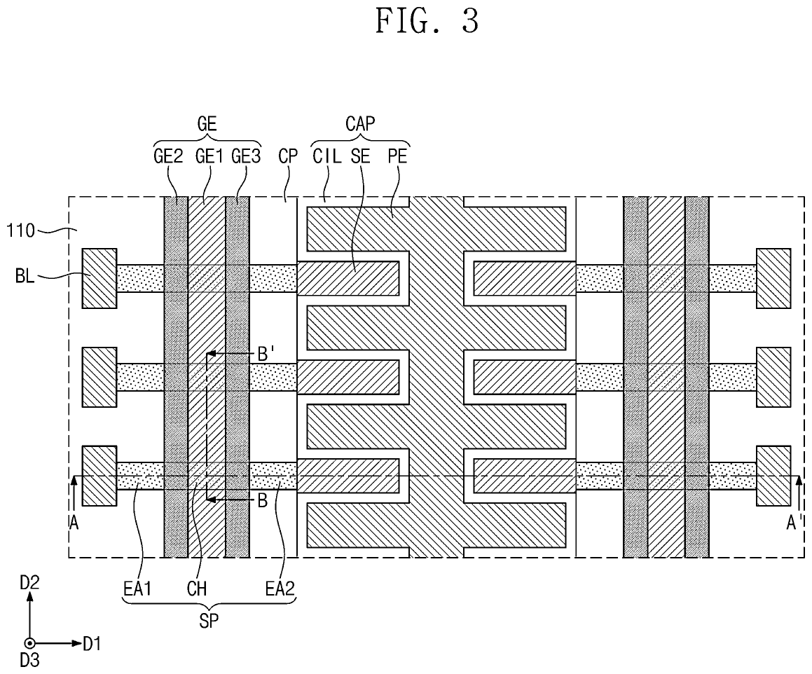

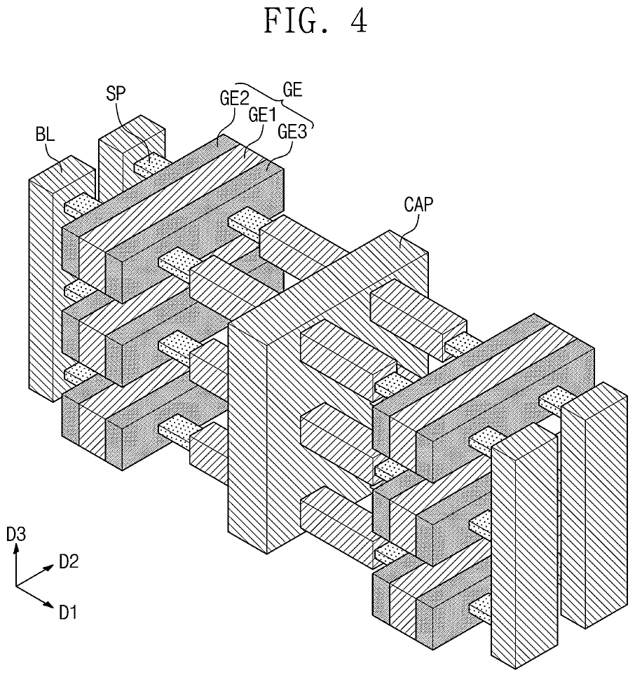

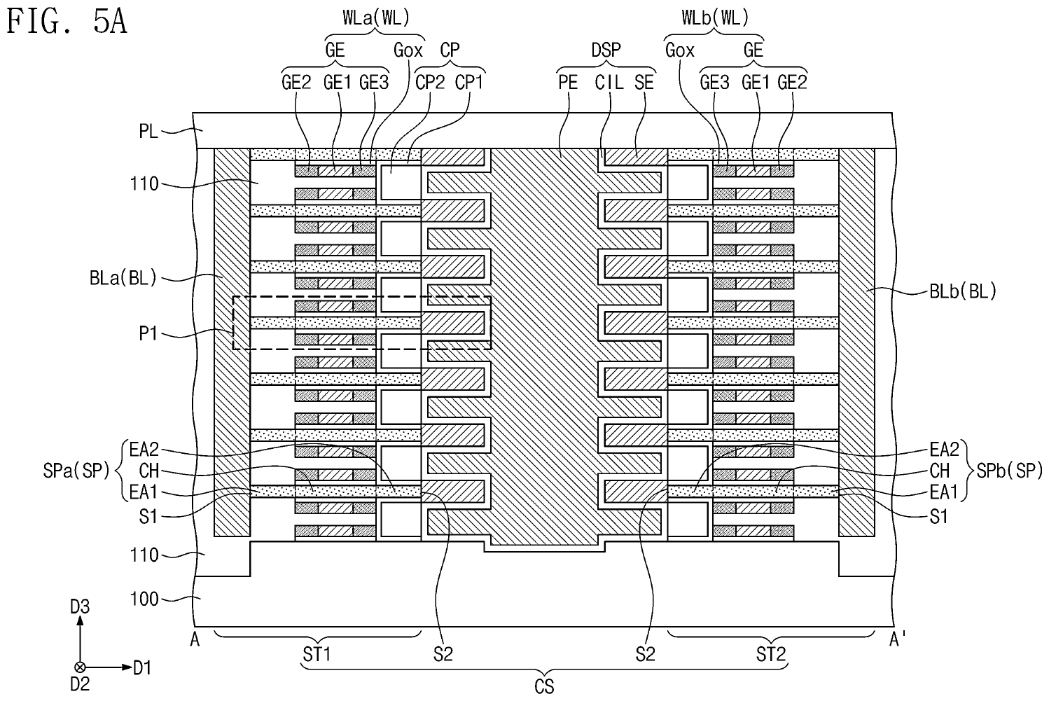

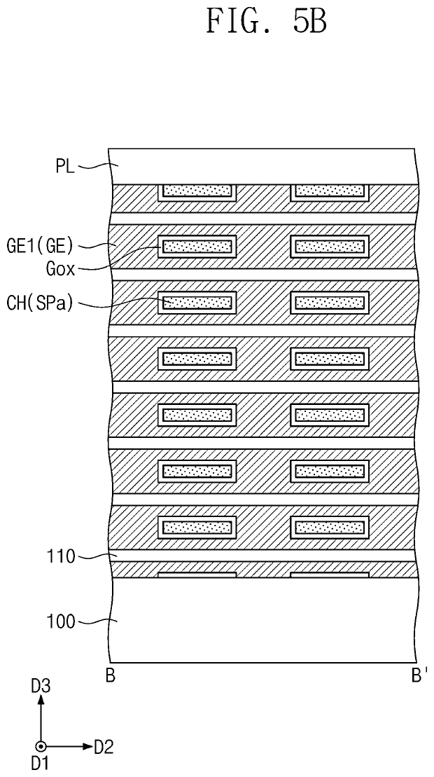

FIG. 3 is a plan view of a three-dimensional semiconductor device according to an embodiment of the inventive concept. FIG. 4 is a perspective view illustrating semiconductor patterns, word lines, bit lines, and a data storage pattern of a three-dimensional semiconductor device according to an embodiment of the inventive concept. FIG. 5A is a cross-sectional view corresponding to line A-A′ in FIG. 3. FIG. 5B is a cross-sectional view corresponding to line B-B′ in FIG. 3.

Referring to FIGS. 3 to 5B, the three-dimensional semiconductor device may include a substrate 100. For example, the substrate 100 may be a semiconductor substrate, an insulating substrate, a silicon-on-insulator (SOI) substrate, or a germanium-on-insulator (GOI) substrate. For example, the semiconductor substrate may be a silicon substrate, a germanium substrate, or a silicon-germanium substrate. The substrate 100 may have a form of a plate extending along a plane defined by the first direction D1 and the second direction D2.

A cell array structure CS may be provided on the substrate 100. The cell array structure CS may include a first stack structure ST1 and a second stack structure ST2 adjacent to each other in the first direction D1, and a data storage pattern DSP therebetween to be described later. For example, although not shown in the drawing, the cell array structure CS may be one of a plurality of cell array structures CS adjacent to each other in the first direction D1. Hereinafter, a single cell array structure CS will be described for convenience of description, but the description will be identically applied to other cell array structures CS.

The first stack structure ST1 and the second stack structure ST2 may each include semiconductor patterns SP, word lines WL, bit lines BL, first capping patterns CP1, second capping patterns CP2, and a buried insulating pattern 110. For example, the first and second stack structures ST1 and ST2 may be mirror-symmetrical with respect to the data storage pattern DSP.

The semiconductor pattern SP may extend on the substrate 100 along the first direction D1. For example, the semiconductor pattern SP may have a form of a bar extending along the first direction D1. The semiconductor pattern SP may be spaced apart from the substrate 100. For example, the semiconductor pattern SP may be floated from the substrate 100.

The semiconductor pattern SP may include a first edge portion EA1 and a second edge portion EA2 spaced apart from each other in the first direction D1, and a channel region CH therebetween. The channel region CH of the semiconductor pattern SP may be surrounded by the word line WL to be described later. The first edge portion EA1 of the semiconductor pattern SP may be adjacent to the bit line BL to be described later. The first edge portion EA1 may be in contact with and may be electrically connected to the bit line BL. The second edge portion EA2 may be adjacent to the data storage pattern DSP to be described later. The second edge portion EA2 may be in contact with and may be electrically connected to the data storage pattern DSP.

The semiconductor pattern SP may have a first side surface S1 and a second side surface S2 opposed thereto. The first side surface S1 may be a side surface of the first edge portion EA1, and the second side surface S2 may be a side surface of the second edge portion EA2. The first side surface S1 of the semiconductor pattern SP may be in contact with the bit line BL, and the second side surface S2 may be in contact with the data storage pattern DSP.

The semiconductor pattern SP may include at least one of a single crystalline semiconductor, a polycrystalline semiconductor, an oxide semiconductor, or a two-dimensional material. For example, the single crystalline semiconductor may be a single crystalline silicon. For example, the polycrystalline semiconductor may be polysilicon. For example, the oxide semiconductor may be indium-gallium-zinc oxide (IGZO). For example, the two-dimensional material may be MoS₂, WS₂, MoSe₂, or WSe₂.

For example, each of the first and second edge portions EA1 and EA2 of the semiconductor pattern SP may include therein an impurity region doped with an impurity (for example, an N-type or P-type impurity). The impurity region may constitute a source/drain region of a transistor.

The semiconductor pattern SP may be provided in plurality. The semiconductor patterns SP may be adjacent to each other in the second direction D2 and the third direction D3. The semiconductor patterns SP adjacent to each other in the third direction D3 may vertically overlap each other. Sidewalls of the semiconductor patterns SP adjacent to each other in the third direction D3 may be aligned with each other.

The semiconductor pattern SP may include a first semiconductor pattern SPa provided in the first stack structure ST1 and a second semiconductor pattern SPb provided in the second stack structure ST2. The first semiconductor pattern SPa and the second semiconductor pattern SPb may be adjacent to each other in the first direction D1. The first edge portion EA1 and the second edge portion EA2 of the first semiconductor pattern SPa may be sequentially disposed along the first direction D1. The first edge portion EA1 and the second edge portion EA2 of the second semiconductor pattern SPb may be sequentially disposed in the first direction D1 in an opposite orientation as the first edge portion EA1 and the second edge portion EA2 of the first semiconductor pattern SPa to have a mirror symmetry with first edge portion EA1 and the second edge portion EA2 of the first semiconductor pattern.

The word line WL may surround the channel region CH of the semiconductor pattern SP, and may extend along the second direction D2. For example, the word line WL may have a structure (e.g., a gate-all-around structure) in which the channel region CH of the semiconductor pattern SP is completely surrounded. One word line WL may surround the channel region CH of each of the semiconductor patterns SP adjacent to each other in the second direction D2. The word lines WL may be provided in plurality. Each word lines WL may surround the channel region CH of the corresponding respective semiconductor pattern SP among the semiconductor patterns SP adjacent to each other in the third direction D3, and may extend along the second direction D2.

The word line WL may include, in the first stack structure ST1, a first word line WLa surrounding the channel region CH of the first semiconductor pattern SPa, and may include, in the second stack structure ST2, a second word line WLb surrounding the channel region CH of the second semiconductor pattern SPb.

The word line WL may include a gate dielectric film Gox (also described as a gate dielectric layer) surrounding the channel region CH of the semiconductor pattern SP, and a gate electrode GE surrounding the channel region CH of the semiconductor pattern SP on the gate dielectric film Gox.

The gate dielectric film Gox may include a single film selected from a high-k dielectric film, a silicon oxide film, a silicon nitride film, and a silicon oxynitride film, or a combination thereof. In the present disclosure, a material having a high dielectric constant (high-k) is defined as a material having a higher dielectric constant than silicon oxide.

The gate electrode GE may include a first gate electrode GE1 having a first work function, a second gate electrode GE2 having a second work function and disposed on one side surface (e.g., a first side surface) of the first gate electrode GE1, and a third gate electrode GE3 having a third work function and disposed on the other side surface opposed to the one side surface (e.g., a second surface opposite the first side surface) of the first gate electrode GE1. According to some embodiments, neither the second gate electrode GE2 nor the third gate electrode GE3 are formed on a top surface or bottom surface of the first gate electrode GE1. The second gate electrode GE2 may be adjacent to the first edge portion EA1 of the semiconductor pattern SP, and the third gate electrode GE3 may be adjacent to the second edge portion EA2 of the semiconductor pattern SP. The second gate electrode GE2 may be interposed between the first gate electrode GE1 and the bit line BL, and the third gate electrode GE3 may be interposed between the first gate electrode GE1 and the data storage pattern DSP.

According to aspects of the inventive concept, the second work function of the second gate electrode GE2 and the third work function of the third gate electrode GE3 may be each smaller than the first work function of the first gate electrode GE1. For example, the second work function of the second gate electrode GE2 and the third work function of the third gate electrode GE3 may be the same as each other. Accordingly, during an operation of the three-dimensional semiconductor device, a gate-induced drain leakage (GIDL) phenomenon generated in the semiconductor pattern SP may be reduced. As a result, an amount of holes accumulated in the semiconductor pattern SP may be reduced, and a leakage current caused by the holes may be reduced. Therefore, reliability of the three-dimensional semiconductor device may be improved.

The first gate electrode GE1 may include or be a first material having the first work function. The second gate electrode GE2 may include or be a second material having the second work function. The third gate electrode GE3 may include or be a third material having the third work function. In some embodiments, the first material may be different from each of the second material and the third material. The work function of each of the second and third materials may be smaller than the work function of the first material.

For example, the first material may include or be at least one of Ti, TiN, TiSiN, TiON, W, WN, Mo, MON, MoOₓN_{y}, Ta, TaN, or poly Si. For example, the second material and the third material may each include or be at least one of Li, Na, K, Cs, Rb, Sr, Ba, Ca, Ce, Sm, Eu, Mg, Sc, Y, Hf, Tl, As, La, Nd, Gd, Tb, Lu, Th, U, Mn, Al, Ga, In, Pb, Cd, Bi, Zr, Ti, TiN, or poly Si doped with an N-type conductive impurity. The second material may be the same material as the third material in some embodiments.

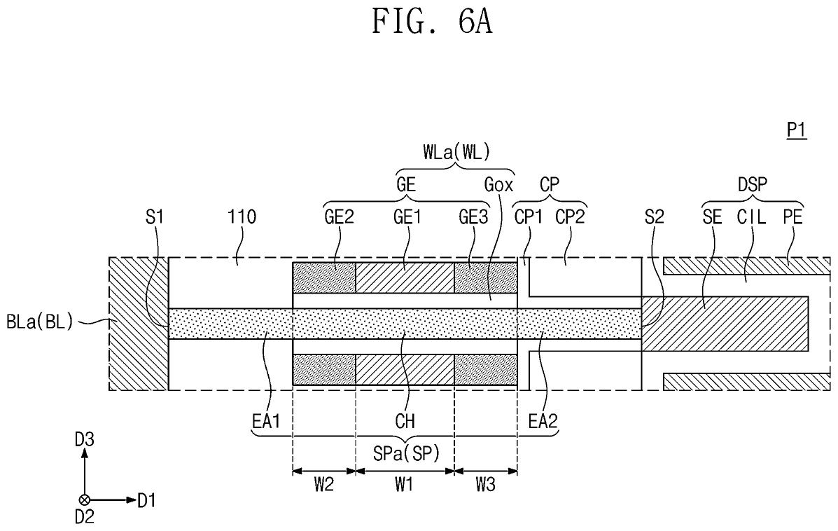

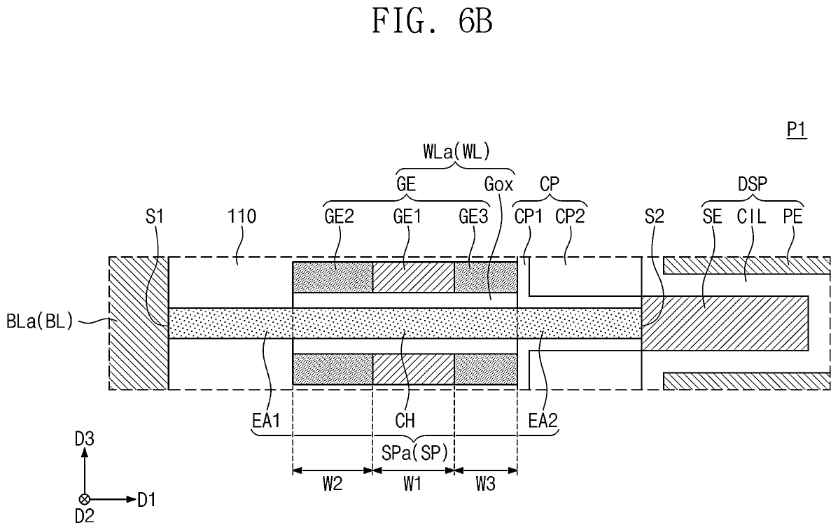

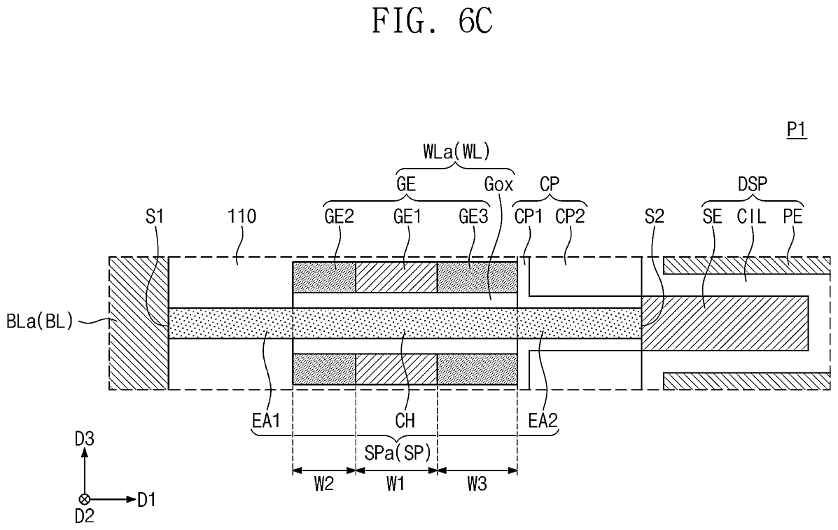

Hereinafter, various embodiment of first to third gate electrodes GE1, GE2, and GE3 will be described with reference to FIGS. 6A to 6C.

Referring to FIG. 6A, with respect to the first direction D1, the first gate electrode GE1 may have a first width W1, the second gate electrode GE2 may have a second width W2, and the third gate electrode GE3 may have a third width W3. The first width W1 may be greater than the second and third widths W2 and W3, but an embodiment is not limited thereto. The second width W2 and the third width W3 may be substantially the same as each other.

As an example, the second gate electrode GE2 and the third gate electrode GE3 may include or be formed of the same material. For example, the second material and the third material may be the same as each other. Accordingly, the second work function and the third work function may be substantially the same as each other.

As another example, the second gate electrode GE2 and the third gate electrode GE3 may include or be formed of different materials. For example, the second material and the third material may be different from each other. According to a material included in each of the second material and the third material, the second work function may be smaller than the third work function, or the third work function may be smaller than the second work function.

As an example, when the first edge portion EA1 of the semiconductor pattern SP is more vulnerable to the gate-induced drain leakage (GIDL) phenomenon than the second edge portion EA2, the second material may have a lower work function than the third material. In this example, the second work function of the second gate electrode GE2 may be smaller than the third work function of the third gate electrode GE3.

As another example, when the second edge portion EA2 of the semiconductor pattern SP is more vulnerable to the gate-induced drain leakage (GIDL) phenomenon than the first edge portion EA1, the third material may have a lower work function than the second material. In this example, the third work function of the third gate electrode GE3 may be smaller than the second work function of the second gate electrode GE2.

Referring to FIGS. 6B and 6C, the second gate electrode GE2 and the third gate electrode GE3 may be asymmetrical with respect to the first gate electrode GE1. The second material may be the same as or different from the third material. The second material may be the same as or different from the second material in FIG. 6A, and the third material may be the same as or different from the third material in FIG. 6A.

Referring to FIG. 6B, the second width W2 may be greater than the third width W3. The second width W2 may be greater than the second width W2 in FIG. 6A. Accordingly, a region in which the second gate electrode GE2 and the semiconductor pattern SP overlap each other may be greater than a region, described with reference to FIG. 6A, in which the second gate electrode GE2 and the semiconductor pattern SP overlap each other. As a result, the gate-induced drain leakage (GIDL) phenomenon in the region of the semiconductor pattern SP adjacent to the second gate electrode GE2 may be reduced further than that described with reference to FIG. 6A.

Referring to FIG. 6C, the third width W3 may be greater than the second width W2. The third width W3 may be greater than the third width W3 in FIG. 6A. Accordingly, a region in which the third gate electrode GE3 and the semiconductor pattern SP overlap each other may be greater than a region, described with reference to FIG. 6A, in which the third gate electrode GE3 and the semiconductor patterns SP overlap each other. As a result, the gate-induced drain leakage (GIDL) phenomenon in the region of the semiconductor pattern SP adjacent to the third gate electrode GE3 may be reduced further than that described with reference to FIG. 6A.

Referring to FIGS. 3 to 5B again, the bit line BL may be provided on the first side surface S1 (e.g., a side surface of the first edge portion EA1) of the semiconductor pattern SP. The bit line BL may extend along the first side surface S1 of the semiconductor pattern SP in the third direction D3. Accordingly, one bit line BL may be in contact with and may be electrically connected to the first side surface S1 of each of the semiconductor patterns SP adjacent to each other in the third direction D3. The bit line BL may be provided in plurality. The bit lines BL may be adjacent to each other along the second direction D2.

The bit line BL may be a single film including one material or a composite film including at least two materials. For example, the bit line BL may include or be formed of at least one of a metal material (for example, Ti, Mo, W, Cu, Al, Ta, Ru, Ir, Co, or the like), a metal nitride (for example, a nitride of Ti, Mo, W, Cu, Al, Ta, Ru, Ir, Co, or the like), or a metal silicide (for example, a silicide of Ti, Mo, W, Cu, Al, Ta, Ru, Ir, Co, or the like).

The bit lines BL may include, in the first stack structure ST1, a first bit line BLa provided on the first side surface S1 of the first semiconductor pattern SPa, and a second bit line BLb provided on the first side surface S1 of the second semiconductor pattern SPb.

The data storage pattern DSP may be interposed between the first stack structure ST1 and the second stack structure ST2. The data storage pattern DSP may be interposed between the first semiconductor pattern SPa and the second semiconductor pattern SPb. The data storage pattern DSP may be in contact with the second side surface S2 (e.g., a side surface of the second edge portion EA2) of the first semiconductor pattern SPa, and may be electrically connected to the first semiconductor pattern SPa. The data storage pattern DSP may be in contact with the second side surface S2 of the second semiconductor pattern SPb, and may be electrically connected to the second semiconductor pattern SPb.

The data storage pattern DSP may include a storage electrode SE, a plate electrode PE, and a capacitor dielectric film CIL therebetween. For example, the three-dimensional semiconductor device may be a dynamic random access memory (DRAM), and in this case, the data storage pattern DSP may be used as a capacitor. The storage electrode SE may be spaced apart from the plate electrode PE by the capacitor dielectric film CIL.

The storage electrode SE and the plate electrode PE may each include a conductive material. For example, the storage electrode SE and the plate electrode PE may each include or be formed of at least one of silicon (Si) doped with an impurity, silicon germanium (SiGe) doped with an impurity, a metal material (for example, Ti, Mo, W, Cu, Al, Ta, Ru, Ir, Co, Pt, Au, Ag, or the like), a metal nitride (for example, a nitride of Ti, Mo, W, Cu, Al, Ta, Ru, Ir, Co, Pt, Au, Ag, or the like), titanium silicon nitride (for example, TiSiN), titanium aluminum nitride (for example, TiAlN), tantalum aluminum nitride (for example, TaAlN, or the like), a conductive oxide (for example, PtO, RuO₂, IrO₂, SRO(SrRuO₃), BSRO((Ba,Sr)RuO₃), CRO(CaRuO₃), LSCo), or a metal silicide. The storage electrode SE and the plate electrode PE may be each a single film composed of a single material, or a composite film including at least two materials.

As an example, the capacitor dielectric film CIL may include or be at least one of a metal oxide such as HfO₂, ZrO₂, Al₂O₃, La₂O₃, Ta₂O₃, and TiO₂, or a dielectric material, having a perovskite structure, such as SrTiO₃ (STO), (Ba,Sr) TiO₃ (BST), BaTiO₃, PZT, PLZT.

As another example, the data storage pattern DSP may be a variable resistor pattern capable of being switched to two resistance states by an electrical pulse. In this case, the data storage pattern DSP may include a phase-change material of which a crystalline state is changed according to an amount of current, a perovskite compound, a transition metal oxide, a magnetic material, a ferromagnetic material, or an antiferromagnetic material.

The storage electrode SE may extend on the second side surface S2 of the first semiconductor pattern SPa along the first direction D1 and may protrude from the second side surface S2 of the first semiconductor pattern SPa toward the second stack structure ST2 in the first direction D1. The storage electrode SE may extend on the second side surface S2 of the second semiconductor pattern SPb along the first direction D1 and may protrude from the second side surface S2 of the second semiconductor pattern SPb toward the first stack structure ST1 in the first direction D1. Although not shown in the drawing, a silicide pattern (not shown) may be provided between the storage electrode SE and the first semiconductor pattern SPa, and the storage electrode SE and the second semiconductor pattern SPb. The silicide pattern may include a metal silicide (for example, a silicide of Ti, Mo, W, Cu, Al, Ta, Ru, Ir, Co, or the like). The storage electrode SE may be provided in plurality, and the storage electrodes SE may be adjacent to each other in the third direction D3.

The plate electrode PE may include a region partially extending along the third direction D3, and another region protruding from the region in the first direction D1 or an opposite direction of the first direction D1. The other region of the plate electrode PE may be interposed between the storage electrodes SE adjacent to each other in the third direction D3.

The buried insulating pattern 110 may be provided on the substrate 100. The buried insulating pattern 110 may cover a side surface of the cell array structure CS. The buried insulating pattern 110 may be interposed between the bit line BL and the word line WL, between the semiconductor patterns SP adjacent to each other in the third direction D3, between the first edge portions EA1 of the semiconductor patterns SP adjacent to each other in the second direction D2, and between the word lines WL adjacent to each other in the third direction D3. The buried insulating pattern 110 may be or include a single film or a composite film including an insulating material.

A capping pattern CP may be provided in the cell array structure CS. The capping pattern CP may be interposed between the word lines WL and the data storage pattern DSP. The capping pattern CP may be interposed between the semiconductor patterns SP adjacent to each other in the third direction D3. The capping pattern CP may be interposed between the second edge portions EA2 of the semiconductor patterns SP adjacent to each other in the second direction D2.

The capping pattern CP may include a first capping pattern CP1 surrounding the second edge portion EA2 of the semiconductor pattern SP, and a second capping pattern CP2 on the first capping pattern CP1. The first capping pattern CP1 may conformally cover the second edge portion EA2 of the semiconductor pattern SP and a side surface of the word line WL. The first capping pattern CP1 and the second capping pattern CP2 may each include an insulating material. The second capping pattern CP2 may be or include a single film or a composite film.

A protective film PL may be provided on the cell array structure CS. The protective film PL may cover upper surfaces of the first stack structure ST1, the second stack structure ST2, and the data storage pattern DSP. The protective film PL may include a single film or a composite film including an insulating material. A plurality of upper lines (not shown) may be included in the protective film PL. A portion of the upper conductive lines may be electrically connected to the bit line BL, and the other portion of the upper conductive lines may be electrically connected to the data storage pattern DSP. In addition, although not shown in the drawing, word line pads (not shown) may be provided on a side surface of the cell array structure CS, and may be electrically connected to the word lines WL.

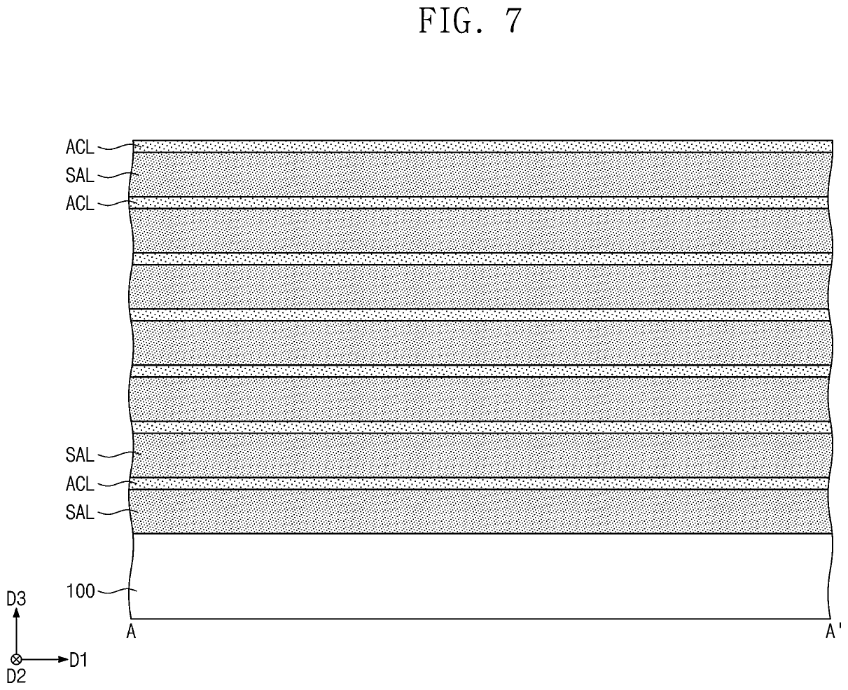

Hereinafter, a method for manufacturing a three-dimensional semiconductor device according to an embodiment of the inventive concept will be described with reference to FIGS. 7 to 20. In order to simplify description, description duplicated with those made above will be omitted, and differences will be mainly described.

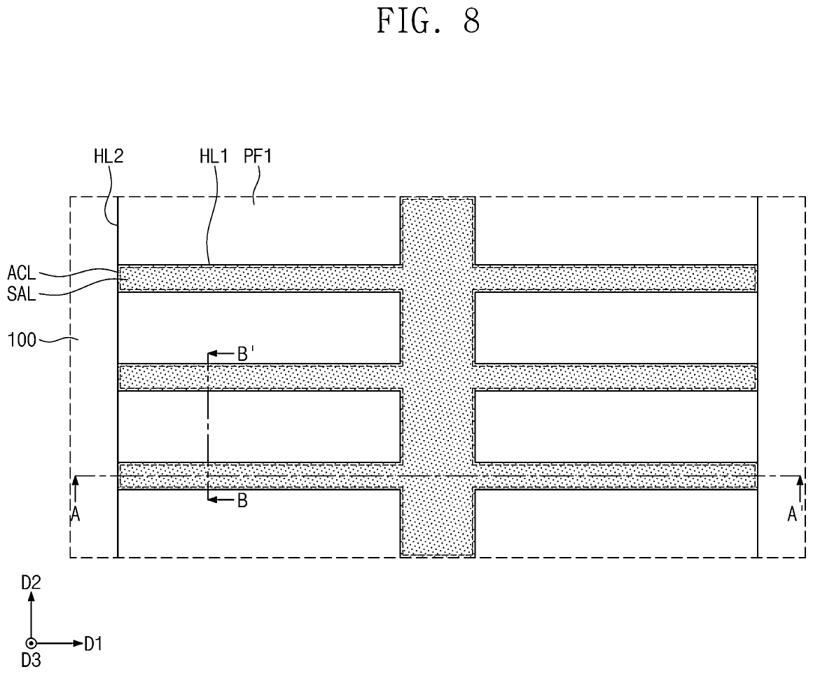

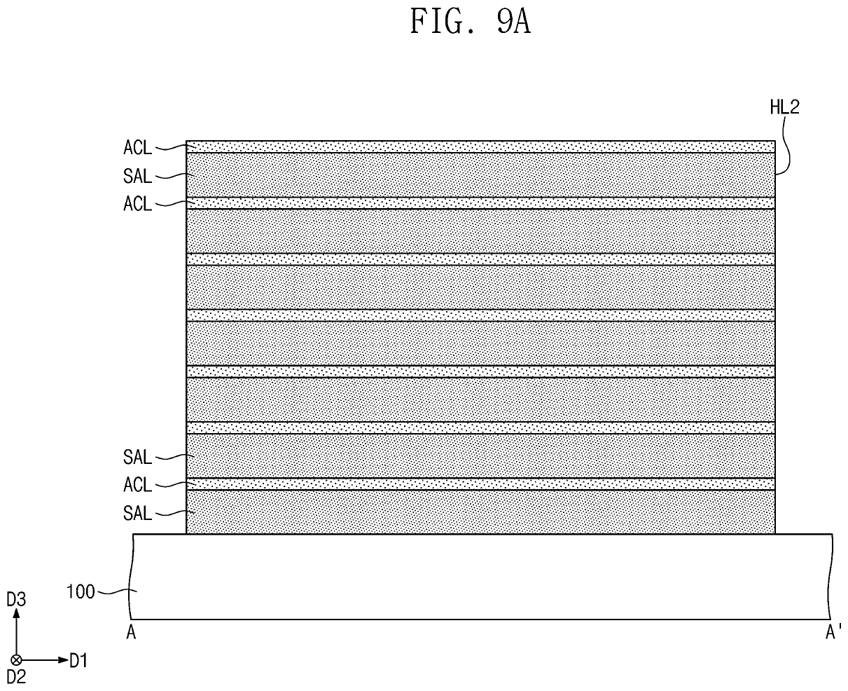

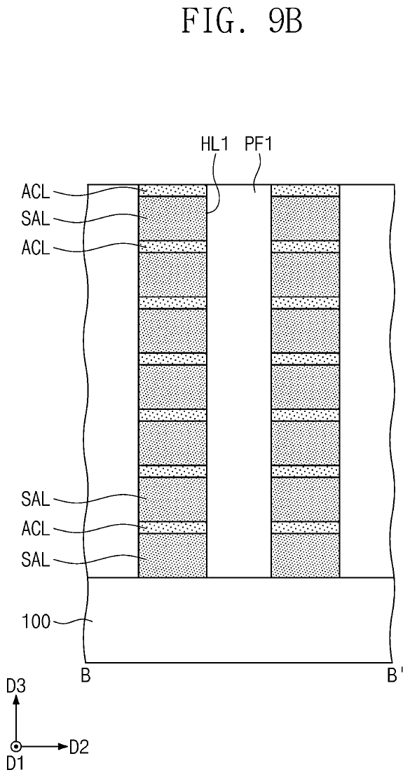

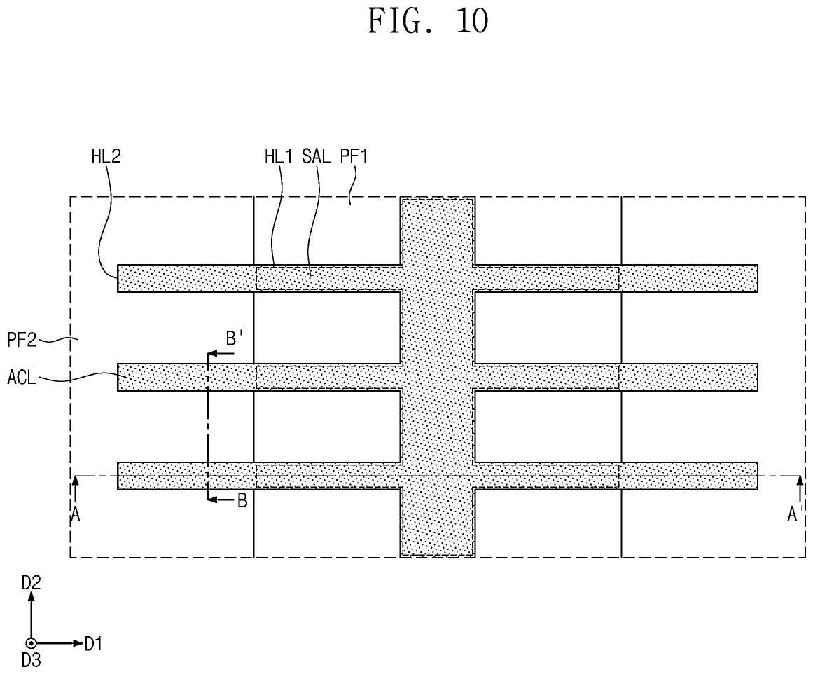

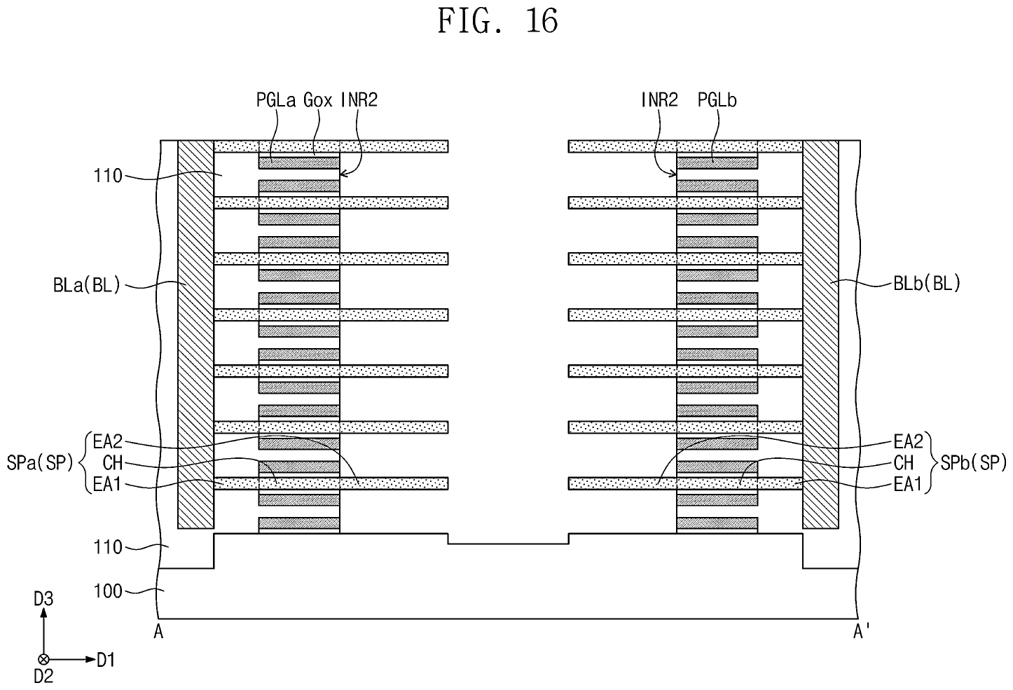

FIGS. 7 to 20 are diagrams illustrating a method for manufacturing a three-dimensional semiconductor device according to an embodiment of the inventive concept. More particularly, FIGS. 7 and 16 are cross-sectional views corresponding to line A-A′ in FIG. 3. FIGS. 8, 10, 12, 14, 17, and 19 are plan views of the three-dimensional semiconductor device according to an embodiment of the inventive concept. FIGS. 9A, 11A, 13, 15A, 18A, and 20 are respectively cross-sectional views corresponding to line A-A′ in FIGS. 8, 10, 12, 14, 17, and 19. FIGS. 9B, 11B, 15B, and 18B are respectively cross-sectional views corresponding to line B-B′ in FIGS. 8, 10, 14, and 17.

Referring to FIGS. 3 and 7, a substrate 100 may be prepared. Sacrificial layers SAL and active layers ACL may be formed to be alternately stacked on the substrate 100. The sacrificial layers SAL and the active layers ACL may each include or be a semiconductor material. The sacrificial layers SAL may include or be a material capable of having an etching selectivity with the active layers ACL. Accordingly, when a process of removing the sacrificial layers SAL to be described later is performed, even if the sacrificial layers SAL are removed, the active layers ACL may not be removed or may be removed less than the sacrificial layers SAL. For example, the active layers ACL may include or be one among silicon (Si), germanium (Ge), and silicon germanium (SiGe), and the sacrificial layers SAL may include or be one, different from the active layers ACL, among silicon (Si), germanium (Ge), and silicon germanium (SiGe). For example, the active layers ACL may be silicon (Si), and the sacrificial layers SAL may be silicon germanium (SiGe). The sacrificial layers SAL may have a greater thickness than the active layers ACL with respect to the third direction D3.

Referring to FIGS. 8 to 9B, first holes HL1 may be formed on the substrate 100 by partially removing each of the sacrificial layers SAL and the active layers ACL. The first holes HL1 may be formed to be adjacent to each other in the first and second directions D1 and D2. An upper surface of the substrate 100 may be partially exposed to the outside by the first holes HL1. Through the removing process, the sacrificial layers SAL and the active layers ACL may be formed to include regions extending long in the first direction D1 and regions extending long in the second direction D2.

First preliminary filling patterns PF1 may partially cover the exposed upper surface of the substrate 100, and may be formed to fill the inside of the first holes HL1. For example, the first preliminary filling pattern PF1 may include or be an insulating material. The first preliminary filling patterns PF1 may be formed to be adjacent to each other in the first and second directions D1 and D2.

Second holes HL2 may be formed on the substrate 100 by partially removing regions, among the sacrificial layers SAL and the active layers ACL, extending long in the second direction D2. The second holes HL2 may be formed to extend along the second direction D2. Both of side surfaces of the sacrificial layers SAL and the active layers ACL may be exposed to the outside by the second holes HL2. During a process of forming the second holes HL2, an upper portion of the substrate 100 may be partially recessed to a predetermined depth. The upper surface of the substrate 100 may be partially exposed to the outside by the second holes HL2.

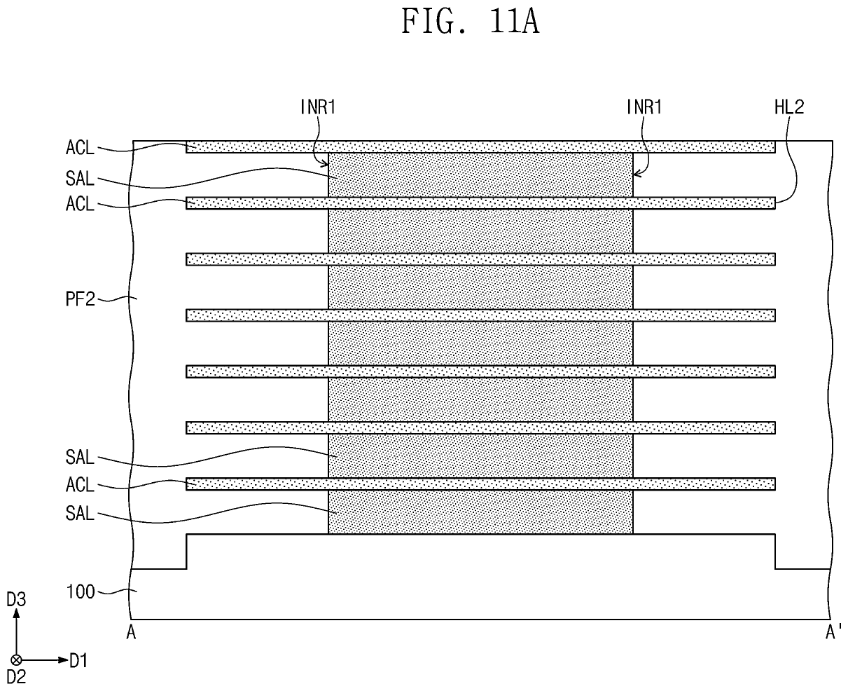

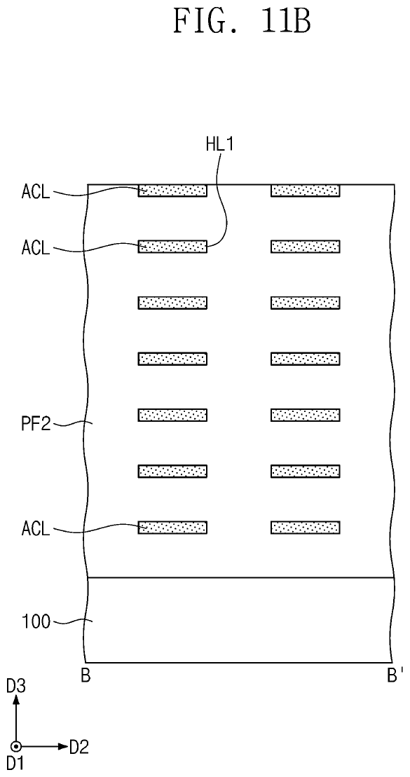

Referring to FIGS. 10 to 11B, both of the exposed side surfaces of the sacrificial layers SAL may be selectively removed through the second holes HL2. Accordingly, first internal regions INR1 may be formed between the active layers ACL adjacent to each other in the third direction D3. During the process of removing, each of the first preliminary filling patterns PF1 may be partially removed at the same time. The sidewalls of the first preliminary filling patterns PF1 may be aligned with sidewalls of the sacrificial layers SAL.

A second preliminary filling pattern PF2 may be formed to fill the first internal regions INR1, a region in which the first preliminary filling patterns PF1 are partially removed, and the inside of the second holes HL2. The second preliminary filling pattern PF2 may cover and surround the active layers ACL not vertically overlapping the sacrificial layers SAL. The second preliminary filling pattern PF2 may include a single film or composite film including an insulating material. For example, the second preliminary filling pattern PF2 may include or be formed of at least one of silicon oxide or silicon nitride.

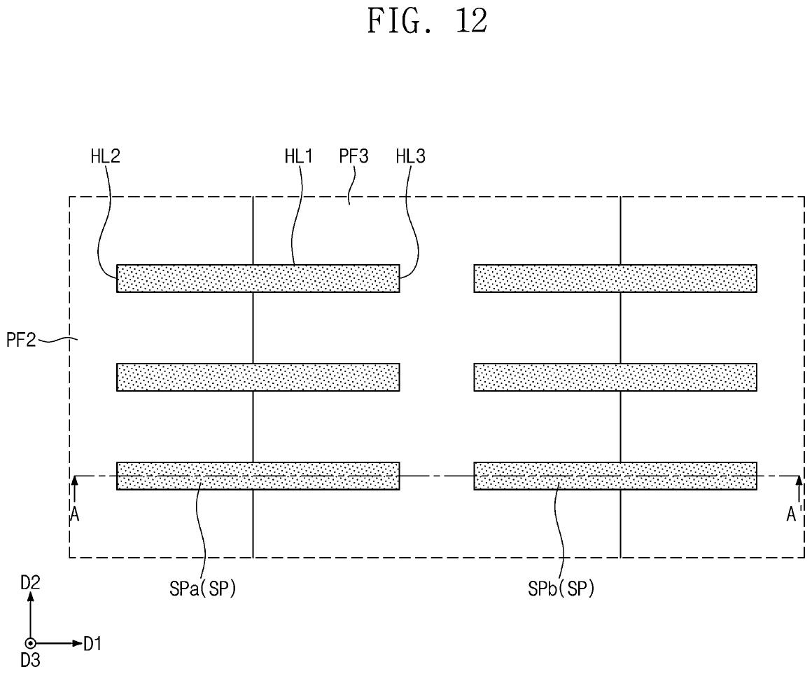

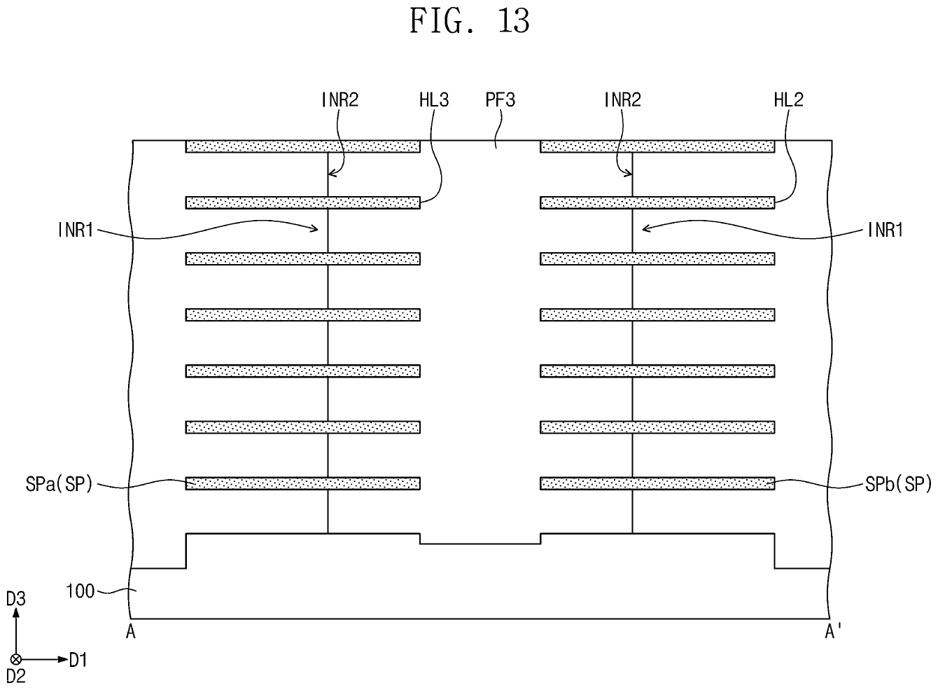

Referring to FIGS. 12 and 13, a third hole HL3 may be formed on the substrate 100 by removing a region, among the sacrificial layers SAL and the active layers ACL, extending long in the second direction D2. During a process of forming the third holes HL3, one active layer ACL may be separated to the semiconductor patterns SP adjacent to each other in the second direction D2. The semiconductor pattern SP may include the first semiconductor pattern SPa and the second semiconductor pattern SPb adjacent to each other in the first direction D1. During the process of forming the third holes HL3, the sacrificial layers SAL may be exposed to the outside again.

The exposed sacrificial layers SAL may be entirely removed on the substrate 100 through the third holes HL3. Accordingly, second internal regions INR2 may be formed between a few regions of the active layers ACL not overlapping the second preliminary filling pattern PF2. During the process of removing, the first preliminary filling patterns PF1 may be entirely removed on the substrate 100. Thereafter, a third preliminary filling pattern PF3 may be formed to fill the second internal regions INR2, a region in which the first preliminary filling patterns PF1 are removed, and the inside of the third holes HL3. The third preliminary filling pattern PF3 may include a single film or composite film including an insulating material. For example, the third preliminary filling pattern PF3 may include at least one of silicon oxide or silicon nitride.

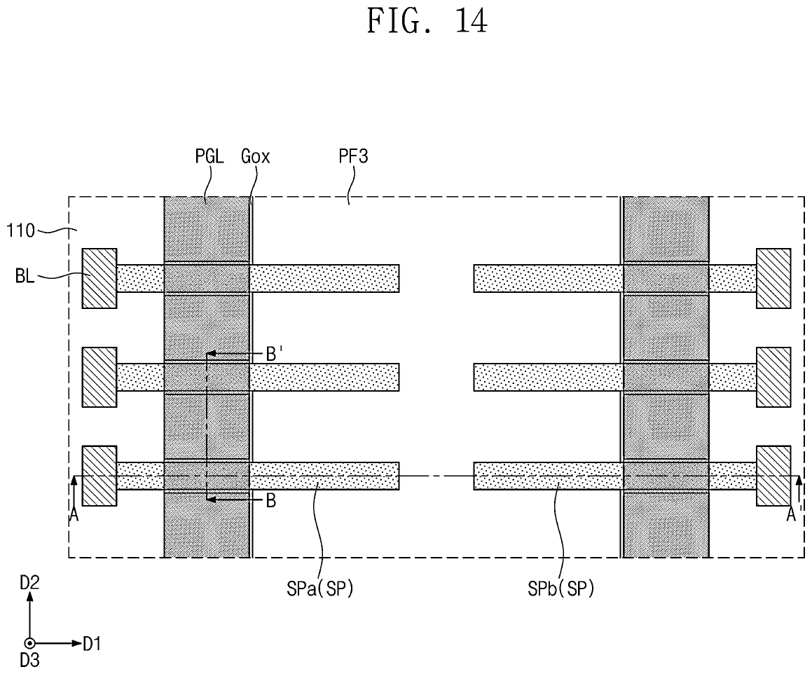

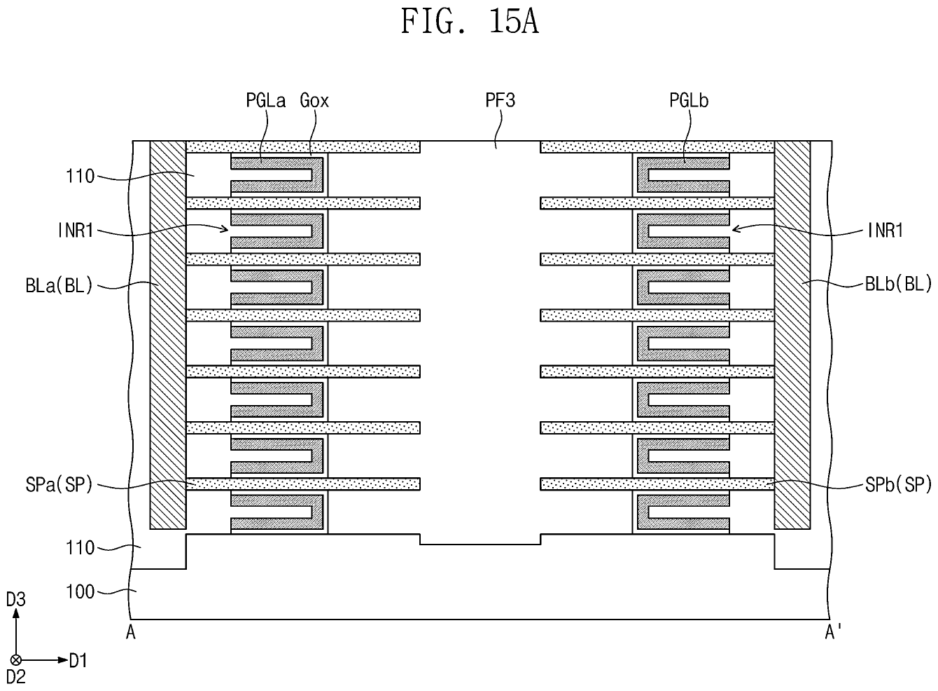

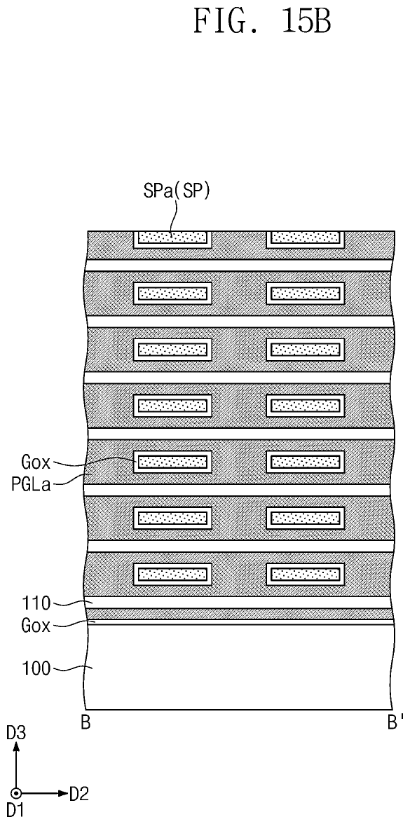

Referring to FIGS. 14 to 15B, the second preliminary filling pattern PF2 may be removed on the substrate 100. Thereafter, the gate dielectric film Gox and preliminary gate conductive films PGLa and PGLb may be sequentially formed in the first internal regions INR1. The gate dielectric film Gox and the preliminary gate conductive films PGLa and PGLb may be formed to partially sequentially conformally cover the semiconductor pattern SP. The gate dielectric film Gox and the preliminary gate conductive films PGLa and PGLb may be formed to partially cover and surround the semiconductor pattern SP. One gate dielectric film Gox and one preliminary gate conductive film PGLa or PGLb may be formed to partially cover and surround each of the semiconductor patterns SP adjacent to each other in the second and third directions D2 and D3. Thereafter, the buried insulating pattern 110 may be formed in a region in which the first internal regions INR1 and the second preliminary filling pattern PF2 are removed.

The bit lines BL may be formed to penetrate the buried insulating pattern 110 and be in contact with one side surfaces of the semiconductor patterns SP. The bit lines BL may include first bit lines BLa in contact with the first semiconductor patterns SPa and the second bit lines BLb in contact with the second semiconductor patterns SPb.

Referring to FIGS. 3 and 16, the third preliminary filling pattern PF3 may be removed on the substrate 100. During the process of removing, the gate dielectric film Gox and the preliminary gate conductive films PGLa and PGLb may be removed together. Accordingly, one gate dielectric film Gox may be separated to a plurality of gate dielectric films Gox adjacent to each other in the second and third directions D2 and D3. In addition, one preliminary gate conductive film PGLa or PGLb may be separated to a plurality of preliminary gate electrodes PGEa and PGEb adjacent to each other in the second and third directions D2 and D3. The gate dielectric film Gox may surround a corresponding semiconductor pattern SP among the semiconductor patterns SP. The preliminary gate electrodes PGEa and PGEb may surround a corresponding semiconductor pattern SP among the semiconductor patterns SP.

During the process of removing, the second internal regions INR2 may be exposed to the outside. One side surface of each of the preliminary gate electrodes PGEa and PGEb may be exposed to the outside by the second internal regions INR2.

The preliminary gate electrodes PGEa and PGEb may include first preliminary gate electrodes PGEa surrounding the first semiconductor patterns SPa and second preliminary gate electrodes PGEb surrounding the second semiconductor patterns SPb.

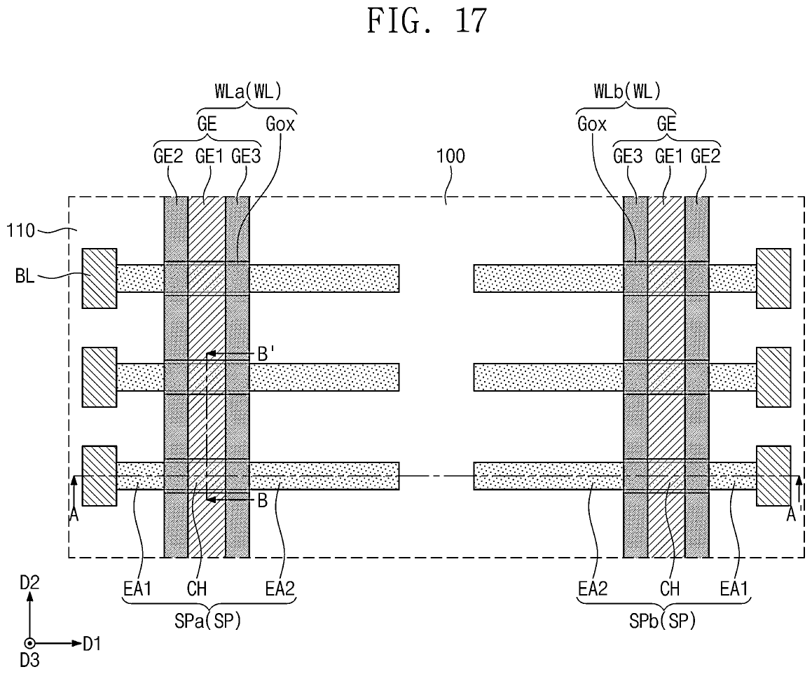

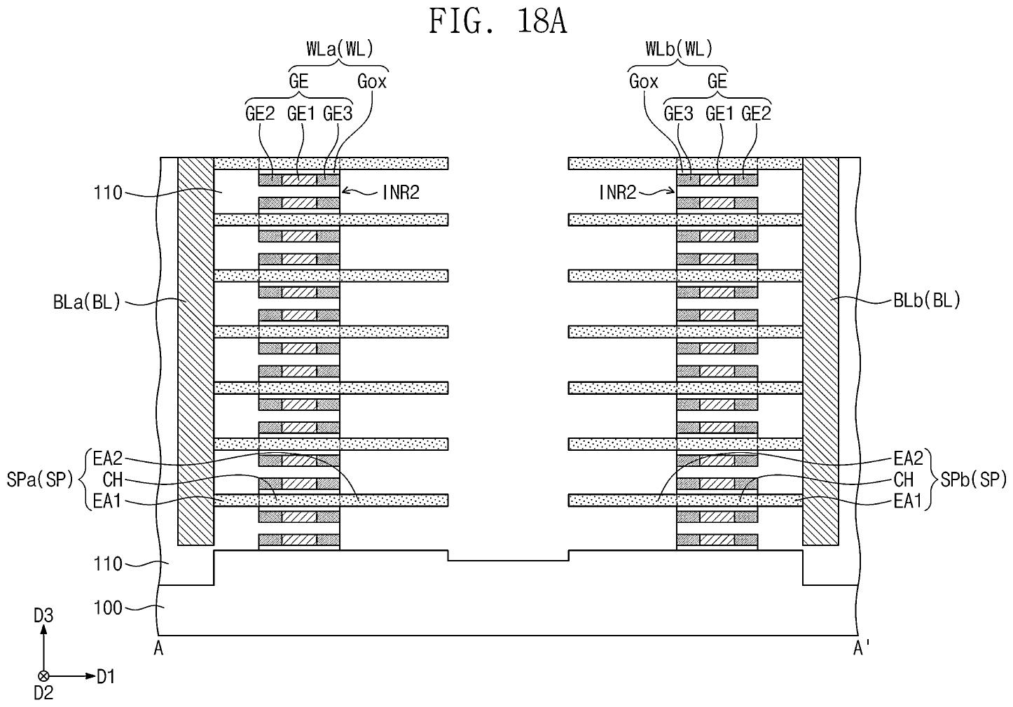

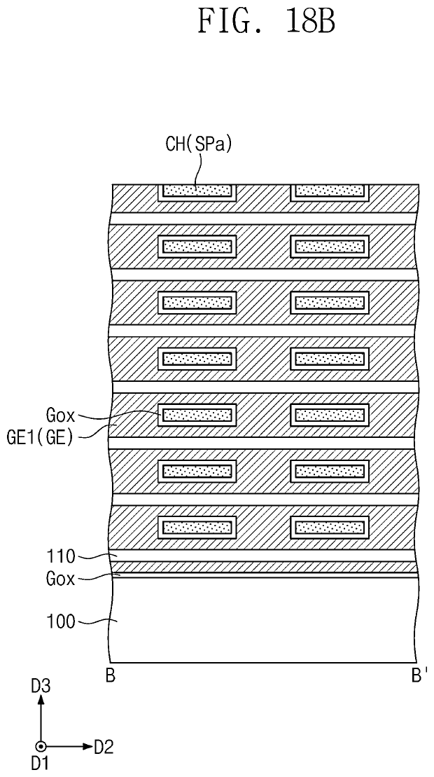

Referring to FIGS. 17 to 18B, a process of removing a portion of each of the preliminary gate electrodes PGEa and PGEb exposed by the second internal regions INR2 may be performed. After the process of removing, a remaining portion of each of the preliminary gate electrodes PGEa and PGEb may constitute the second gate electrodes GE2 described with reference to FIGS. 3 to 5B. Thereafter, the first gate electrode GE1 and the third gate electrode GE3 may be sequentially formed on a side surface of each of the second gate electrodes GE2. The first gate electrode GE1 and the third gate electrode GE3 may be formed to surround the semiconductor pattern SP.

The gate dielectric film Gox and the first to third gate electrodes GE1, GE2, and GE3 surrounding the first semiconductor pattern SPa may constitute the first word line WLa. The gate dielectric film Gox and the first to third gate electrodes GE1, GE2, and GE3 surrounding the second semiconductor pattern SPb may constitute the second word line WLb.

A region, of the first semiconductor pattern SPa, surrounded by the first word line WLa may constitute the channel region CH of the first semiconductor pattern SPa. A region, of the second semiconductor pattern SPb, surrounded by the second word line WLb may constitute the channel region CH of the second semiconductor pattern SPb.

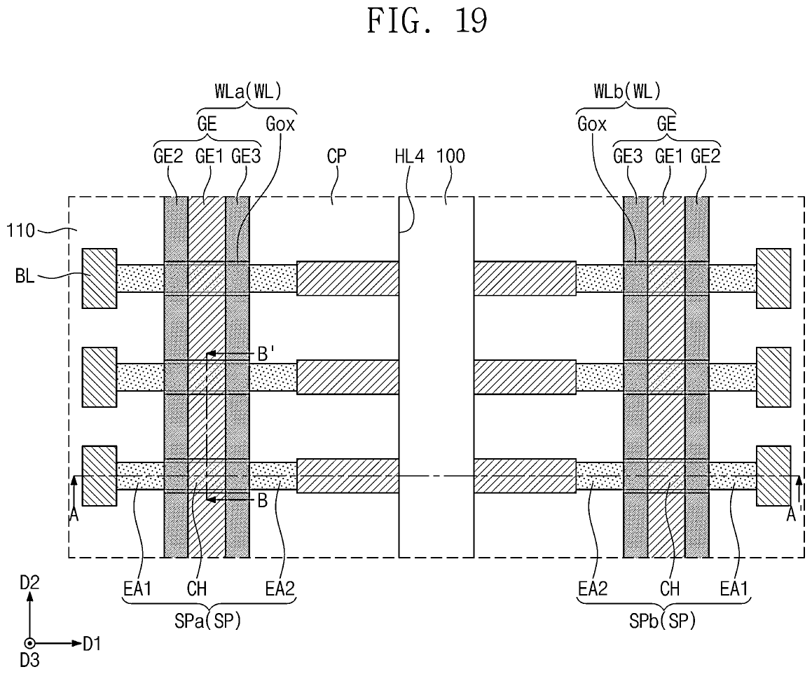

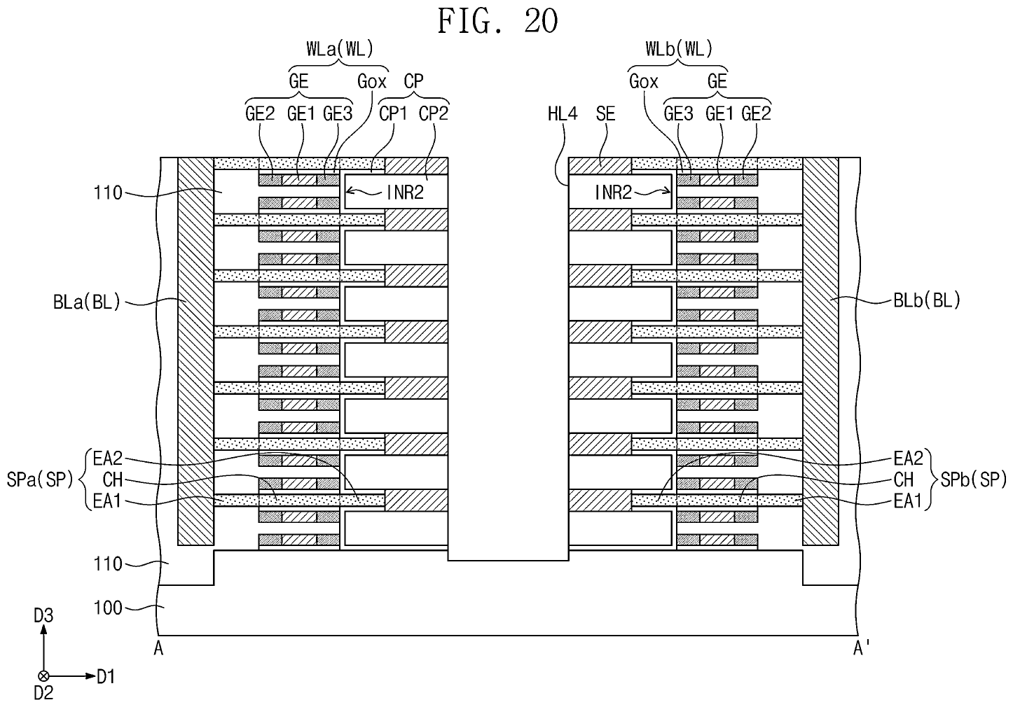

Referring to FIGS. 19 and 20, the capping pattern CP may be formed to fill a region in which the second internal regions INR2 and the third preliminary filling pattern PF3 are removed. The capping pattern CP may include a first capping pattern CP1 conformally covering the second internal regions INR2 and the second edge portion EA2 of the semiconductor patterns SP, and a second capping pattern CP2 filling the remining portion of the second internal regions INR2 and surrounding the second edge portion EA2 of the semiconductor patterns SP.

Thereafter, a fourth hole HL4 may be formed on the substrate 100 by partially removing the capping pattern CP. The fourth hole HL4 may be formed to extend along the second direction D2. The second edge portions EA2 of the semiconductor patterns SP may be exposed to the outside by the fourth hole HL4.

A process of partially removing the exposed second edge portions EA2 of the semiconductor patterns SP may be performed by the fourth hole HL4. During the process of removing, a process of partially removing the first capping pattern CP1 may be performed together.

The storage electrodes SE may be formed on the second edge portions EA2 of the semiconductor patterns SP. For example, forming the storage electrodes SE may include forming silicide patterns (not shown) on the second edge portions EA2 of the semiconductor patterns SP, and forming the storage electrode SE through a selective epitaxial growth (SEG) process using the silicide patterns as seeds.

Referring to FIGS. 3 to 5B again, a process of partially removing the second capping pattern CP2 may be performed. Accordingly, a side surface of the second capping pattern CP2 may be aligned with a side surface of the second edge portion EA2 of the semiconductor pattern SP. Thereafter, the capacitor dielectric film CIL may be formed to conformally cover the storage electrodes SE. The plate electrode PE may be formed to cover the space between the storage electrodes SE, and a remaining portion of the fourth hole HL4 described with reference to FIGS. 19 and 20. The storage electrode SE, the capacitor dielectric film CIL, and the plate electrode PE may constitute the data storage pattern DSP. Thereafter, the protective film PL may be formed to cover the cell array structure CS.

According to aspects of the inventive concept, a word line may include a first gate electrode, a second gate electrode on one side surface of the first gate electrode, and a third gate electrode on the other side surface of the first gate electrode. A work function of each of the second gate electrode and the third gate electrode may be smaller than a work function of the first gate electrode. Accordingly, during an operation of a three-dimensional semiconductor device, a gate-induced drain leakage (GIDL) phenomenon generated in a semiconductor pattern may be reduced. As a result, an amount of holes accumulated in the semiconductor pattern may decrease so that a leakage current caused by the holes may be reduced. Accordingly, reliability of the three-dimensional semiconductor device may be improved.

The above description of embodiments of the inventive concept provides an example for description of the inventive concept. Therefore, the inventive concept is not limited to the above embodiments, and it is obvious that various modifications and changes such as combining the above embodiments may be made by those skilled in the art within the technical spirit of the inventive concept.

What is claimed is:

1. A three-dimensional semiconductor device comprising:
a semiconductor pattern spaced apart from a substrate and extending along a first direction parallel to a lower surface of the substrate;
a word line surrounding the semiconductor pattern and extending along a second direction parallel to the lower surface of the substrate and crossing the first direction; and
a bit line extending along a first side surface of the semiconductor pattern along a third direction perpendicular to the lower surface of the substrate,
wherein the word line includes:
a first gate electrode,
a second gate electrode on a first side surface of the first gate electrode, and
a third gate electrode on a second side surface opposite to the first side surface of the first gate electrode, and
wherein a work function of each of the second and third gate electrodes is smaller than a work function of the first gate electrode.

2. The three-dimensional semiconductor device of claim 1, wherein the second gate electrode and the third gate electrode comprise different materials.

3. The three-dimensional semiconductor device of claim 1, wherein the work function of the second gate electrode is smaller than the work function of the third gate electrode.

4. The three-dimensional semiconductor device of claim 1, wherein the work function of the third gate electrode is smaller than the work function of the second gate electrode.

5. The three-dimensional semiconductor device of claim 1, wherein with respect to the first direction, a width of the second gate electrode is greater than a width of the third gate electrode.

6. The three-dimensional semiconductor device of claim 1, wherein with respect to the first direction, a width of the third gate electrode is greater than a width of the second gate electrode.

7. The three-dimensional semiconductor device of claim 1, further comprising a data storage pattern on a second side surface opposite to the first side surface of the semiconductor pattern.

8. The three-dimensional semiconductor device of claim 1, wherein the first gate electrode comprises at least one of Ti, TiN, TiSiN, TiON, W, WN, Mo, MON, MoOₓN_{y}, Ta, TaN, or poly Si.

9. The three-dimensional semiconductor device of claim 1, wherein the second gate electrode comprises at least one of Li, Na, K, Cs, Rb, Sr, Ba, Ca, Ce, Sm, Eu, Mg, Sc, Y, Hf, Tl, As, La, Nd, Gd, Tb, Lu, Th, U, Mn, Al, Ga, In, Pb, Cd, Bi, Zr, Ti, TiN, or poly Si doped with an N-type conductive impurity and the third gate electrode comprises at least one of Li, Na, K, Cs, Rb, Sr, Ba, Ca, Ce, Sm, Eu, Mg, Sc, Y, Hf, Tl, As, La, Nd, Gd, Tb, Lu, Th, U, Mn, Al, Ga, In, Pb, Cd, Bi, Zr, Ti, TiN, or poly Si doped with an N-type conductive impurity.

10. A three-dimensional semiconductor device comprising:
a semiconductor pattern spaced apart from a substrate and extending along a first direction parallel to a lower surface of the substrate;
a word line surrounding the semiconductor pattern and extending along a second direction parallel to the lower surface of the substrate and crossing the first direction; and
a bit line extending along a first side surface of the semiconductor pattern along a third direction perpendicular to the lower surface of the substrate,
wherein the word line includes:
a first gate electrode including a first material,
a second gate electrode provided on a first side surface of the first gate electrode and including a second material, and
a third gate electrode provided on a second side surface opposite to the first side surface of the first gate electrode and including a third material,
the first material includes a material different from the second and third materials, and
wherein a work function of each of the second material and the third material is smaller than a work function of the first material.

11. The three-dimensional semiconductor device of claim 10, wherein the first material comprises at least one of Ti, TIN, TiSiN, TiON, W, WN, Mo, MON, MoOₓN_{y}, Ta, TaN, or poly Si.

12. The three-dimensional semiconductor device of claim 10, wherein the second material comprises at least one of Li, Na, K, Cs, Rb, Sr, Ba, Ca, Ce, Sm, Eu, Mg, Sc, Y, Hf, Tl, As, La, Nd, Gd, Tb, Lu, Th, U, Mn, Al, Ga, In, Pb, Cd, Bi, Zr, Ti, TiN, or poly Si doped with an N-type conductive impurity, and the third material comprises at least one of Li, Na, K, Cs, Rb, Sr, Ba, Ca, Ce, Sm, Eu, Mg, Sc, Y, Hf, Tl, As, La, Nd, Gd, Tb, Lu, Th, U, Mn, Al, Ga, In, Pb, Cd, Bi, Zr, Ti, TiN, or poly Si doped with an N-type conductive impurity.

13. The three-dimensional semiconductor device of claim 10, wherein the second material and the third material comprise different materials.

14. The three-dimensional semiconductor device of claim 10, wherein the work function of the second material is smaller than the work function of the third material.

15. The three-dimensional semiconductor device of claim 10, wherein the work function of the third material is smaller than the work function of the second material.

16. The three-dimensional semiconductor device of claim 10, wherein with respect to the first direction, a width of the second gate electrode is greater than a width of the third gate electrode.

17. The three-dimensional semiconductor device of claim 10, wherein with respect to the first direction, a width of the third gate electrode is greater than a width of the second gate electrode.

18. A three-dimensional semiconductor device comprising:
a first stack structure on a substrate, and a second stack structure adjacent to the first stack structure in a first direction parallel to a lower surface of the substrate; and
a data storage pattern between the first stack structure and the second stack structure,
wherein the first stack structure includes:
a first semiconductor pattern spaced apart from the substrate and extending along the first direction,
a first word line surrounding the first semiconductor pattern and extending along a second direction parallel to the lower surface of the substrate and crossing the first direction, and
a first bit line extending along a first side surface of the first semiconductor pattern along a third direction perpendicular to the lower surface of the substrate,
wherein the first word line includes:
a first gate electrode,
a second gate electrode on a first side surface of the first gate electrode, and
a third gate electrode on a second side surface opposite to the first side surface of the first gate electrode, and
a work function of each of the second and third gate electrodes is smaller than a work function of the first gate electrode.

19. The three-dimensional semiconductor device of claim 18, wherein the second stack structure comprises:
a second semiconductor pattern spaced apart from the substrate and extending along the first direction;
a second word line surrounding the second semiconductor pattern and extending along the second direction; and
a second bit line extending on one side surface of the second semiconductor pattern along the third direction.

20. The three-dimensional semiconductor device of claim 18, wherein the second and third gate electrodes comprise different materials, and/or widths of the second and third gate electrodes along the first direction are different from each other.
